(19) United States
(12) Patent Application Publication
(10) Pub. No.: US 2025/0283219 A1
(43) Pub. Date: Sep. 11, 2025

(54) METHODS OF DEPOSITING SILICON NITRIDE

(71) Applicant: Applied Materials, Inc., Santa Clara, CA (US)

(72) Inventors: Hanhong Chen, Milpitas, CA (US); Zhejun Zhang, Santa Clara, CA (US); Hao Zhang, San Jose, CA (US); Jianheng Li, Sunnyvale, CA (US); Yi-Min Lin, San Jose, CA (US); Chi-Chou Lin, San Jose, CA (US)

(73) Assignee: Applied Materials, Inc., Santa Clara, CA (US)

(21) Appl. No.: 19/070,718

(22) Filed: Mar. 5, 2025

Related U.S. Application Data
(60) Provisional application No. 63/562,437, filed on Mar. 7, 2024.

(51) Int. Cl. C23C 16/455; C23C 16/02; C23C 16/34; C23C 16/511

(52) U.S. Cl. CPC C23C 16/45536; C23C 16/0272; C23C 16/345; C23C 16/511

(57) ABSTRACT

Methods of depositing silicon nitride (SiₓN_{y}) are disclosed. Exemplary methods include exposing a substrate in a semiconductor processing chamber to a first silicon-containing precursor; exposing the substrate to a first plasma comprising one or more of ammonia (NH₃) or hydrogen (H₂) to form a first silicon nitride (SiₓN_{y}) layer directly on the substrate; treating the first silicon nitride (SiₓN_{y}) layer with a second plasma comprising nitrogen (N₂) to form a treated first silicon nitride (SiₓN_{y}) layer; and depositing a second silicon nitride (SiₓN_{y}) layer directly on the treated first silicon nitride (SiₓN_{y}) layer by a plasma-enhanced atomic layer deposition (PEALD) process.

### CROSS-REFERENCE TO RELATED APPLICATIONS

This application claims priority to U.S. Provisional Application No. 63/562,437, filed Mar. 7, 2024, the entire disclosure of which is incorporated by reference herein.

### TECHNICAL FIELD

Embodiments of the disclosure generally relate to the field of semiconductor device manufacturing. More particularly, embodiments of the disclosure are directed to methods of depositing silicon nitride (SiₓN_{y}) by plasma-enhanced atomic layer deposition (PEALD).

### BACKGROUND

Silicon nitride (SiₓN_{y}) films have attractive dielectric material properties. These films have been proposed and tested for applications from front-end of line (FEOL) to back-end of line (BEOL) processes and parts of semiconductor and microelectronic devices. Generally, FEOL refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer.

Low temperature, e.g., less than or equal to 600° C., atomic layer deposition (ALD) of silicon nitride (SiₓN_{y}) films are used in many semiconductor applications. Without intending to be bound by any particular theory, it is thought that many of these lower temperature applications are deposited by plasma-enhanced ALD (PEALD) due to poor film quality by low temperature thermal processes, e.g., a thermal ALD process.

For example, current PEALD approaches, e.g., (1) exposure to silicon-containing precursor, purge, exposure to thermal ammonia (NH₃), followed by nitrogen (N₂) plasma, or (2) exposure to silicon-containing precursor, purge, exposure to ammonia (NH₃) plasma, followed by nitrogen (N₂) plasma, may independently form non-stoichiometric nitridation layers from the substrate nitridation. It has been found that in cases where the substrate comprises one or more of silicon (Si), germanium (Ge), silicon germanium (SiGe), tungsten (W), nickel (Ni), cobalt (Co), or titanium (Ti), PEALD of silicon nitride (SiₓN_{y}) directly on the substrate forms one or more of silicon nitride (SiₓN_{y}), germanium nitride (GeNₓ), silicon germanium nitride (SiGeNₓ), tungsten nitride (WNₓ), nickel nitride (NiNₓ), cobalt nitride (CoNₓ), or titanium nitride (TiNₓ) from the substrate.

The formation of non-stoichiometric nitridation layers of the substrate, such as, for example, one or more of silicon nitride (SiₓN_{y}), germanium nitride (GeNₓ), silicon germanium nitride (SiGeNₓ), tungsten nitride (WNₓ), nickel nitride (NiNₓ), cobalt nitride (CoNₓ), or titanium nitride (TiNₓ), is undesirable due to an increased dielectric layer thickness or increased resistivity of underlying metal layers by forming a metal nitride.

Accordingly, there is a need for improved PEALD of SiₓN_{y} without forming a non-stoichiometric nitridation layer of the substrate.

### SUMMARY

One or more embodiments of the disclosure are directed to a method of depositing silicon nitride (SiₓN_{y}). The method comprises exposing a substrate in a semiconductor processing chamber to a first silicon-containing precursor; exposing the substrate to a first plasma comprising one or more of ammonia (NH₃) or hydrogen (H₂) to form a first silicon nitride (SiₓN_{y}) layer directly on the substrate; treating the first silicon nitride (SiₓN_{y}) layer with a second plasma comprising nitrogen (N₂) to form a treated first silicon nitride (SiₓN_{y}) layer; and depositing a second silicon nitride (SiₓN_{y}) layer directly on the treated first silicon nitride (SiₓN_{y}) layer by a plasma-enhanced atomic layer deposition (PEALD) process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of the present disclosure and are therefore not to be considered limiting of its scope, for the disclosure may admit to other equally effective embodiments.

FIG. 1 illustrates a process flow diagram of a method of depositing silicon nitride (SiₓN_{y}) according to one or more embodiments of the disclosure;

FIG. 2A illustrates a cross-sectional schematic view of a substrate according to one or more embodiments of the disclosure;

FIG. 2B illustrates a cross-sectional schematic view of a substrate according to one or more embodiments of the disclosure;

FIG. 2C illustrates a cross-sectional schematic view of a substrate according to one or more embodiments of the disclosure;

FIG. 3 illustrates a schematic representation of a processing tool comprising a modular high-frequency emission source with a plasma showerhead assembly that comprises a plurality of applicators according to one or more embodiments of the disclosure;

FIG. 4 illustrates a block diagram of a high-frequency emission module according to one or more embodiments of the disclosure;

FIG. 5 illustrates a schematic exploded perspective view of the plasma showerhead assembly of FIG. 3 according to one or more embodiments of the disclosure; and

FIG. 6 illustrates a cross-sectional view of a processing tool according to one or more embodiments.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the Figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiments,” or “an embodiment” means that a particular feature, structure, material, or characteristic described in connection with the embodiment is included in at least one embodiment of the disclosure. Thus, the appearances of the phrases such as “in one embodiment,” “in some embodiments,” “in certain embodiments,” “in one or more embodiments,” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

Embodiments of the disclosure provide a substrate comprising one or more of silicon (Si), germanium (Ge), silicon germanium (SiGe), tungsten (W), nickel (Ni), cobalt (Co), or titanium (Ti).

The substrate may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., hydrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. As used herein, the term “thermal process(es)” refers to a deposition technique that does not involve the use of plasma. As used herein, the term “plasma” refers to a composition have ionically charged species and uncharged neutral and radical species.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate or substrate surface by atomic layer deposition (ALD) or plasma-enhanced atomic layer deposition (PEALD) are conformal. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

Plasma-enhanced atomic layer deposition (PEALD) methods add a plasma exposure to traditional ALD methods. In some PEALD methods, a nitrogen source is provided as the plasma. The primary benefit of PEALD methods is the relatively low substrate temperature, e.g., less than or equal to 600° C., during processing.

Embodiments of the disclosure advantageously provide methods of depositing silicon nitride (SiₓN_{y}) without forming non-stoichiometric nitridation layers from the substrate. In embodiments where the substrate comprises one or more of silicon (Si), germanium (Ge), silicon germanium (SiGe), tungsten (W), nickel (Ni), cobalt (Co), or titanium (Ti), embodiments of the disclosure advantageously provide methods of depositing silicon nitride (SiₓN_{y}) without forming one or more of silicon nitride (SiₓN_{y}), germanium nitride (GeNₓ), silicon germanium nitride (SiGeNₓ), tungsten nitride (WNₓ), nickel nitride (NiNₓ), cobalt nitride (CoNₓ), or titanium nitride (TiNₓ) from the substrate. Advantageously, in one or more embodiments, the methods prevent non-stoichiometric nitridation layer formation and do not increase dielectric layer thickness. Advantageously, in one or more embodiments, the methods prevent non-stoichiometric nitridation layer formation and does not increase resistivity of underlying metal layers comprising conductive material.

Some embodiments advantageously provide methods of depositing silicon nitride (SiₓN_{y}) for FEOL and BEOL processes and parts. Some embodiments advantageously provide methods of depositing silicon nitride (SiₓN_{y}) having improved film quality.

There are multiple metrics used to measure SiₓN_{y} film quality. One of the most common metrics used to measure SiₓN_{y} film quality is the wet etch rate of the deposited film under dilute hydrofluoric (HF) acid etch solution, such as dilute HF 100:1. Embodiments of the disclosure advantageously provide a SiₓN_{y} film that has a reduced etch amount in Angstroms (Å) using dilute HF 100:1, which represents an improved wet etch rate, compared to a current PEALD approaches.

Additional embodiments of the disclosure provide a plasma showerhead assembly, e.g., an assembly, for a processing tool. In one or more embodiments, the assembly comprises a conductive plate and a dielectric faceplate.

In one or more embodiments, the conductive plate includes a first surface and a second surface opposite to the first surface defining a conductive plate thickness, a plurality of resonator openings extending from the first surface through the conductive plate to the second surface of the conductive plate, gas channels within the conductive plate thickness, a plurality of conductive plate gas openings on the second surface of the conductive plate in fluid communication with the gas channels within the conductive plate thickness.

In one or more embodiments, the dielectric faceplate comprises a first surface and a second surface opposite to the first surface defining a dielectric faceplate thickness, a plurality of dielectric resonator protruding from the first surface and configured so that the resonators fit into the plurality of the resonator openings of the conductive plate when assembled, each resonator having a geometric center; and a plurality of dielectric faceplate gas openings extending through the dielectric faceplate thickness.

In one or more embodiments, the assembly comprises a plurality of o-rings surrounding the conductive plate gas openings and the dielectric faceplate gas openings, wherein the dielectric faceplate gas openings are in fluid communication with the conductive plate gas openings and the o-rings are configured to seal the dielectric faceplate gas openings and the conductive plate gas openings from atmospheric pressure.

The assembly described herein is a microwave plasma source that may be used to generate a microwave plasma of any of the plasma compositions described herein. Advantageously, the energy of the microwaves can be tuned low enough that it does not substantially damage dielectric materials (e.g., no plasma and/or low temperature). Further, the disclosed methods are self-limiting by only affecting the SiₓN_{y} layers deposited and not the other layers, such as a dielectric layer, in the structures.

The embodiments of the disclosure are described by way of the Figures, which illustrate processes, substrates, and apparatuses in accordance with one or more embodiments of the disclosure. The processes and resulting substrates shown are merely illustrative of the disclosed processes, and the skilled artisan will recognize that the disclosed processes are not limited to the illustrated applications.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

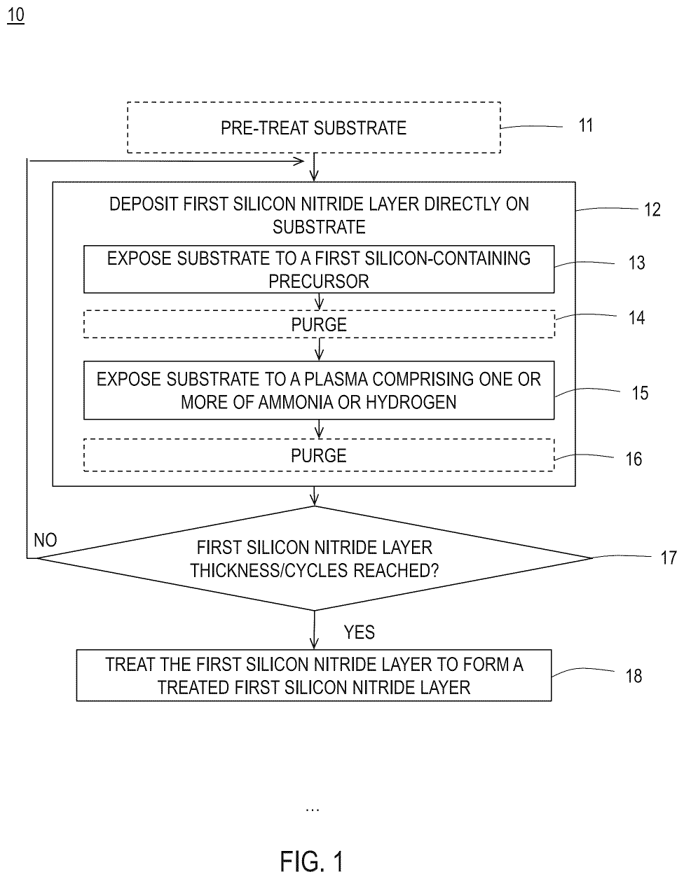

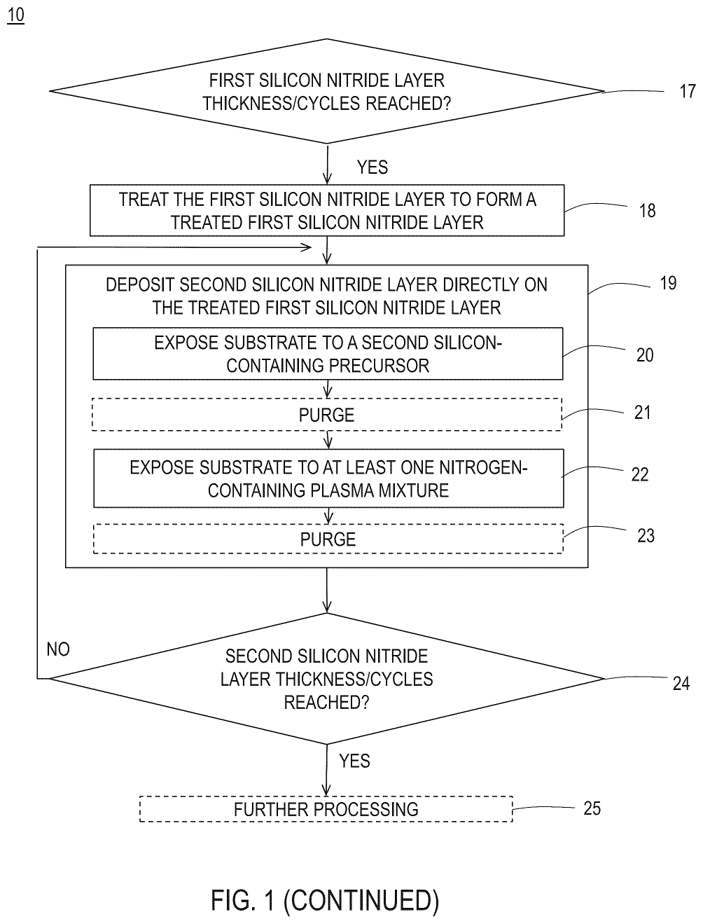

FIG. 1 illustrates a process flow diagram of a method 10 of depositing silicon nitride (SiₓN_{y}). The method 10 shown in FIG. 1 spans two (2) sheets in the Figures. The method 10 may be performed at any suitable processing conditions, and the processing conditions may vary depending upon the application for which the silicon nitride (SiₓN_{y}) is formed.

The method 10 begins by optionally pre-treating the substrate 50 (operation 11). The pre-treatment can be any suitable pre-treatment known to the skilled artisan. Suitable pre-treatments include, but are not limited to, pre-heating, cleaning, soaking, or native oxide removal, as examples.

The method 10 of one or more embodiments comprises a first cycle 12, decision point 17, a treatment process at operation 18, a second cycle 19, and decision point 24. The first cycle 12 comprises depositing a first silicon nitride (SiₓN_{y}) layer 54 directly on the substrate 50.

The first cycle 12 begins at operation 13, which comprises exposing the substrate 50 to a first silicon-containing precursor. The first silicon-containing precursor may be any suitable precursor that includes silicon. In some embodiments, the first silicon-containing precursor includes, but is not limited to, one or more of a silane (SiₓH_{y}), a chlorosilane (SiₓH_{y}Cl_{z}), or an iodosilane (SiₓH_{y}I_{z}). In some embodiments, the first silicon-containing precursor includes one or more of silane (SiH₄), disilane (Si₂H₆), chlorosilane (H₃SiCl), dichlorosilane (H₂SiCl₂), trichlorosilane (HSiCl₃), tetrachlorosilane (SiCl₄), iodosilane (H₃ISi), diiodosilane (H₂I₂Si), triiodosilane (HI₃Si), or tetraiodosilane (I₄Si). In some embodiments, the first silicon-containing precursor includes bis(diethylamino)silane (BDEAS).

The first cycle 12 optionally includes purging the substrate 50 at operation 14. In one or more embodiments of FIG. 1, the dashed lines are used to denote that the stated operation is optional.

The first cycle 12 includes, at operation 15, exposing the substrate 50 to a first plasma comprising one or more of ammonia (NH₃) or hydrogen (H₂) to form the first silicon nitride (SiₓN_{y}) layer 54 directly on the substrate 50.

It has been advantageously found that first plasma comprising one or more of ammonia (NH₃) or hydrogen (H₂) prevents formation of one or more of silicon nitride (SiₓN_{y}), germanium nitride (GeNₓ), silicon germanium nitride (SiGeNₓ), tungsten nitride (WNₓ), nickel nitride (NiNₓ), cobalt nitride (CoNₓ), or titanium nitride (TiNₓ) from the substrate.

In one or more embodiments, the first plasma comprises ammonia (NH₃) and hydrogen (H₂). In one or more embodiments, the first plasma consists essentially of ammonia (NH₃) and hydrogen (H₂). In one or more embodiments, the first plasma consists of ammonia (NH₃) and hydrogen (H₂).

In one or more embodiments, the first plasma comprises ammonia (NH₃). In one or more embodiments, the first plasma consists essentially of ammonia (NH₃). In one or more embodiments, the first plasma consists of ammonia (NH₃).

In one or more embodiments, the first plasma comprises hydrogen (H₂). In one or more embodiments, the first plasma consists essentially of hydrogen (H₂). In one or more embodiments, the first plasma consists of hydrogen (H₂).

In one or more embodiments, the first plasma comprises ammonia (NH₃), hydrogen (H₂), and argon (Ar). In one or more embodiments, the first plasma consists essentially of ammonia (NH₃), hydrogen (H₂), and argon (Ar). In one or more embodiments, the first plasma consists of ammonia (NH₃), hydrogen (H₂), and argon (Ar).

In one or more embodiments, the first plasma comprises ammonia (NH₃) and argon (Ar). In one or more embodiments, the first plasma consists essentially of ammonia (NH₃) and argon (Ar). In one or more embodiments, the first plasma consists of ammonia (NH₃) and argon (Ar).

In one or more embodiments, the first plasma comprises hydrogen (H₂) and argon (Ar). In one or more embodiments, the first plasma consists essentially of hydrogen (H₂) and argon (Ar). In one or more embodiments, the first plasma consists of hydrogen (H₂) and argon (Ar).

In one or more embodiments, the first plasma comprises ammonia (NH₃), nitrogen (N₂), hydrogen (H₂), and argon (Ar). In one or more embodiments, the first plasma consists essentially of ammonia (NH₃), nitrogen (N₂), hydrogen (H₂), and argon (Ar). In one or more embodiments, the first plasma consists of ammonia (NH₃), nitrogen (N₂), hydrogen (H₂), and argon (Ar).

In one or more embodiments, the first plasma comprises ammonia (NH₃), nitrogen (N₂), and argon (Ar). In one or more embodiments, the first plasma consists essentially of ammonia (NH₃), nitrogen (N₂), and argon (Ar). In one or more embodiments, the first plasma consists of ammonia (NH₃), nitrogen (N₂), and argon (Ar).

In one or more embodiments, the first plasma comprises hydrogen (H₂), nitrogen (N₂), and argon (Ar). In one or more embodiments, the first plasma consists essentially of hydrogen (H₂), nitrogen (N₂), and argon (Ar). In one or more embodiments, the first plasma consists of hydrogen (H₂), nitrogen (N₂), and argon (Ar).

In one or more embodiments, the first plasma comprises ammonia (NH₃), hydrogen (H₂), and helium (He). In one or more embodiments, the first plasma consists essentially of ammonia (NH₃), hydrogen (H₂), and helium (He). In one or more embodiments, the first plasma consists of ammonia (NH₃), hydrogen (H₂), and helium (He).

In one or more embodiments, the first plasma comprises ammonia (NH₃) and helium (He). In one or more embodiments, the first plasma consists essentially of ammonia (NH₃) and helium (He). In one or more embodiments, the first plasma consists of ammonia (NH₃) and helium (He).

In one or more embodiments, the first plasma comprises hydrogen (H₂) and helium (He). In one or more embodiments, the first plasma consists essentially of hydrogen (H₂) and helium (He). In one or more embodiments, the first plasma consists of hydrogen (H₂) and helium (He).

In one or more embodiments, the first plasma comprises ammonia (NH₃), nitrogen (N₂), hydrogen (H₂), and helium (He). In one or more embodiments, the first plasma consists essentially of ammonia (NH₃), nitrogen (N₂), hydrogen (H₂), and helium (He). In one or more embodiments, the first plasma consists of ammonia (NH₃), nitrogen (N₂), hydrogen (H₂), and helium (He).

In one or more embodiments, the first plasma comprises ammonia (NH₃), nitrogen (N₂), and helium (He). In one or more embodiments, the first plasma consists essentially of ammonia (NH₃), nitrogen (N₂), and helium (He). In one or more embodiments, the first plasma consists of ammonia (NH₃), nitrogen (N₂), and helium (He).

In one or more embodiments, the first plasma comprises hydrogen (H₂), nitrogen (N₂), and helium (He). In one or more embodiments, the first plasma consists essentially of hydrogen (H₂), nitrogen (N₂), and helium (He). In one or more embodiments, the first plasma consists of hydrogen (H₂), nitrogen (N₂), and helium (He).

In one or more embodiments, the ammonia (NH₃) in the first plasma has a concentration in a range of from 0.1% to 25%, by atomic percent. In one or more embodiments, the remaining concentration in the first plasma comprises, consists essentially of, or consists of one or more of nitrogen (N₂), hydrogen (H₂), argon (Ar) or helium (He).

In one or more embodiments, the hydrogen (H₂) in the first plasma has a concentration in a range of from 0.1% to 25%, by atomic percent. In one or more embodiments, the remaining concentration in the first plasma comprises, consists essentially of, or consists of one or more of ammonia (NH₃), nitrogen (N₂), argon (Ar) or helium (He).

The first cycle 12 optionally includes purging the substrate 50 at operation 16.

The first silicon nitride (SiₓN_{y}) layer 54 may be formed at any suitable processing pressure and any suitable processing temperature. In one or more embodiments, the first silicon nitride (SiₓN_{y}) layer 54 is formed at a pressure in a range of from 0.1 Torr to 20 Torr. In one or more embodiments, the first silicon nitride (SiₓN_{y}) layer 54 is formed at a temperature in a range of from 100° C. to 600° C.

In one or more embodiments, the first silicon nitride (SiₓN_{y}) layer 54 has a thickness in a range of from 0 Å to 15 Å. Advantageously, the first silicon nitride (SiₓN_{y}) layer 54 prevents formation of one or more of silicon nitride (SiₓN_{y}), germanium nitride (GeNₓ), silicon germanium nitride (SiGeNₓ), tungsten nitride (WNₓ), nickel nitride (NiNₓ), cobalt nitride (CoNₓ), or titanium nitride (TiNₓ) from the substrate 50.

Advantageously, the first silicon nitride (SiₓN_{y}) layer 54 prevents non-stoichiometric nitridation layer formation and does not increase dielectric layer thickness. Advantageously, the first silicon nitride (SiₓN_{y}) layer 54 prevents non-stoichiometric nitridation layer formation and does not increase resistivity of underlying metal layers comprising conductive material.

For example, it has been found that plasmas of differing composition than the above-described first plasma, e.g., nitrogen (N₂) and one or more of argon (Ar) or helium (He), may not prevent formation of one or more of silicon nitride (SiₓN_{y}), germanium nitride (GeNₓ), silicon germanium nitride (SiGeNₓ), tungsten nitride (WNₓ), nickel nitride (NiNₓ), cobalt nitride (CoNₓ), or titanium nitride (TiNₓ) from the substrate 50. In one example, where the first silicon nitride (SiₓN_{y}) layer 54 is formed from a plasma comprising nitrogen (N₂) and argon (Ar) and the first silicon nitride (SiₓN_{y}) layer 54 has a thickness in a range of from 8 Å to 15 Å, the first silicon nitride (SiₓN_{y}) layer 54 prevents formation of one or more of silicon nitride (SiₓN_{y}), germanium nitride (GeNₓ), silicon germanium nitride (SiGeNₓ), tungsten nitride (WNₓ), nickel nitride (NiNₓ), cobalt nitride (CoNₓ), or titanium nitride (TiNₓ) from the substrate 50.

After depositing the first silicon nitride (SiₓN_{y}) layer 54 directly on the substrate 50 in the first cycle 12, the method moves to decision point 17.

At decision point 17, the substrate 50 is evaluated to determine whether or not the first silicon nitride (SiₓN_{y}) layer 54 has reached a predetermined thickness, e.g., a thickness in a range of from 0 Å to 15 Å, or a predetermined number of cycles have been performed. In this regard, the “number of cycles” refers to the first cycle 12. If the conditions are met e.g., the answer to decision point 17 is “YES,” the method 10 continues to operation 18 to treat the first silicon nitride (SiₓN_{y}) layer 54. If the conditions are not met, e.g., the answer to decision point 17 is “NO,” the method 10 returns to optionally operation 11, or the beginning of the first cycle 12 (operation 13). One or more embodiments of the method 10 comprise repeating one or more operations of the method 10 and/or one or more operations of the first cycle 12 to deposit the first silicon nitride (SiₓN_{y}) layer 54 to a predetermined thickness and/or until a predetermined number of cycles have been performed.

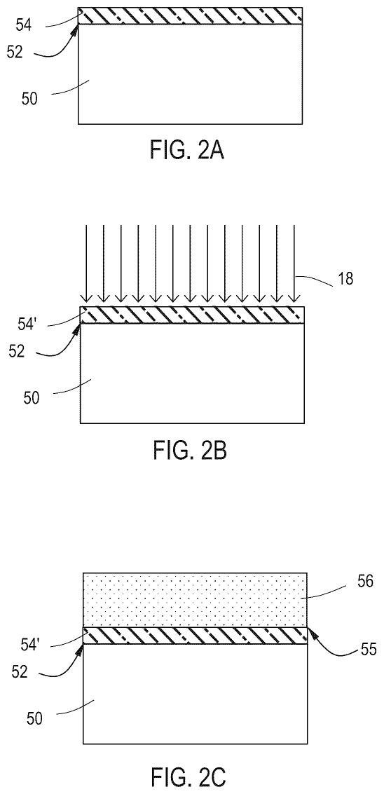

The treatment process of operation 18 comprises treating the first silicon nitride (SiₓN_{y}) layer 54 with a second plasma comprising nitrogen (N₂) to form a treated first silicon nitride (SiₓN_{y}) layer 54′. In FIG. 2B, the treatment process of operation 18 is denoted by the arrows pointed towards a top surface of the first silicon nitride (SiₓN_{y}) layer 54 to form the treated first silicon nitride (SiₓN_{y}) layer 54′.

In one or more embodiments, the second plasma comprises nitrogen (N₂). In one or more embodiments, the second plasma consists essentially of nitrogen (N₂). In one or more embodiments, the second plasma consists of nitrogen (N₂).

In one or more embodiments, the second plasma comprises nitrogen (N₂) and argon (Ar). In one or more embodiments, the second plasma consists essentially of nitrogen (N₂) and argon (Ar). In one or more embodiments, the second plasma consists of nitrogen (N₂) and argon (Ar).

In one or more embodiments, the second plasma comprises nitrogen (N₂) and helium (He). In one or more embodiments, the second plasma consists essentially of nitrogen (N₂) and helium (He). In one or more embodiments, the second plasma consists of nitrogen (N₂) and helium (He).

In one or more embodiments, the nitrogen (N₂) in the second plasma has a concentration in a range of from 0.1% to 25%, by atomic percent. In one or more embodiments, the remaining concentration in the second plasma comprises, consists essentially of, or consists of one or more of argon (Ar) or helium (He).

After treating the first silicon nitride (SiₓN_{y}) layer 54 with the second plasma comprising nitrogen (N₂) to form the treated first silicon nitride (SiₓN_{y}) layer 54′ at operation 18, the method continues to a PEALD process in the second cycle 19.

In one or more embodiments, the PEALD process of the second cycle 19 comprises: exposing the substrate 50 to a second silicon-containing precursor (operation 20); optionally purging the substrate 50 at operation 21; exposing the substrate 50 to at least one nitrogen-containing plasma mixture at operation 22; and optionally purging the substrate at operation 23.

The second silicon-containing precursor may be the same as or different from the first silicon-precursor used in operation 13 of the first cycle 12.

In one or more embodiments, the at least one nitrogen-containing plasma mixture exposure of operation 22 includes exposing the substrate 50 to a first nitrogen-containing plasma mixture comprising ammonia (NH₃), nitrogen (N₂), and one or more of argon (Ar) or helium (He) and/or exposing the substrate 50 to a second nitrogen-containing plasma mixture comprises nitrogen (N₂) and one or more of argon (Ar) or helium (He).

In one or more embodiments, the at least one nitrogen-containing plasma mixture of operation 22 includes exposing the substrate 50 to the first nitrogen-containing plasma mixture comprising ammonia (NH₃), nitrogen (N₂), and one or more of argon (Ar) or helium (He), followed by exposing the substrate 50 to the second nitrogen-containing plasma mixture comprising nitrogen (N₂) and one or more of argon (Ar) or helium (He).

In one or more embodiments, the at least one nitrogen-containing plasma mixture of operation 22 includes exposing the substrate 50 to the second nitrogen-containing plasma mixture comprising nitrogen (N₂) and one or more of argon (Ar) or helium (He), followed by exposing the substrate 50 to the first nitrogen-containing plasma mixture comprising ammonia (NH₃), nitrogen (N₂), and one or more of argon (Ar) or helium (He).

In one or more embodiments, the first nitrogen-containing plasma mixture comprises ammonia (NH₃), nitrogen (N₂), and one or more of argon (Ar) or helium (He). In one or more embodiments, the first nitrogen-containing plasma mixture consists essentially of ammonia (NH₃), nitrogen (N₂), and one or more of argon (Ar) or helium (He). In one or more embodiments, the first nitrogen-containing plasma mixture consists of ammonia (NH₃), nitrogen (N₂), and one or more of argon (Ar) or helium (He).

In one or more embodiments, the first nitrogen-containing plasma mixture comprises ammonia (NH₃), nitrogen (N₂), and argon (Ar). In one or more embodiments, the first nitrogen-containing plasma mixture consists essentially of ammonia (NH₃), nitrogen (N₂), and argon (Ar). In one or more embodiments, the first nitrogen-containing plasma mixture consists of ammonia (NH₃), nitrogen (N₂), and argon (Ar).

In one or more embodiments, the first nitrogen-containing plasma mixture comprises ammonia (NH₃), nitrogen (N₂), and helium (He). In one or more embodiments, the first nitrogen-containing plasma mixture consists essentially of ammonia (NH₃), nitrogen (N₂), and helium (He). In one or more embodiments, the first nitrogen-containing plasma mixture consists of ammonia (NH₃), nitrogen (N₂), and helium (He).

In one or more embodiments, the second nitrogen-containing plasma mixture comprises nitrogen (N₂) and one or more of argon (Ar) or helium (He). In one or more embodiments, the second nitrogen-containing plasma mixture consists essentially of nitrogen (N₂) and one or more of argon (Ar) or helium (He). In one or more embodiments, the second nitrogen-containing plasma mixture consists of nitrogen (N₂) and one or more of argon (Ar) or helium (He).

In one or more embodiments, the second nitrogen-containing plasma mixture comprises nitrogen (N₂) and argon (Ar). In one or more embodiments, the second nitrogen-containing plasma mixture consists essentially of nitrogen (N₂) and argon (Ar). In one or more embodiments, the second nitrogen-containing plasma mixture consists of nitrogen (N₂) and argon (Ar).

In one or more embodiments, the second nitrogen-containing plasma mixture comprises nitrogen (N₂) and helium (He). In one or more embodiments, the second nitrogen-containing plasma mixture consists essentially of nitrogen (N₂) and helium (He). In one or more embodiments, the second nitrogen-containing plasma mixture consists of nitrogen (N₂) and helium (He).

After depositing the second silicon nitride (SiₓN_{y}) layer 56 directly on the treated first silicon nitride (SiₓN_{y}) layer 54′ by the plasma-enhanced atomic layer deposition (PEALD) process in the second cycle 19, the method 10 continues to decision point 24.

At decision point 24, the substrate 50 is evaluated to determine whether or not the second silicon nitride (SiₓN_{y}) layer 56 has reached a predetermined thickness or a predetermined number of cycles have been performed. In this regard, the “number of cycles” refers to the second cycle 19. If the conditions are met e.g., the answer to decision point 24 is “YES,” the method 10 continues to optional post-processing operation 25. The optional post-processing operation 25 can be any suitable process known to the skilled artisan. If the conditions are not met, e.g., the answer to decision point 24 is “NO,” the method 10 returns to the beginning of the second cycle 19 (operation 20). One or more embodiments of the method 10 comprise repeating one or more operations of the method 10 and/or one or more operations of the second cycle 19 to deposit the second silicon nitride (SiₓN_{y}) layer 56 to a predetermined thickness and/or until a predetermined number of cycles have been performed.

In one or more embodiments, the method 10 comprises operation 11, the first cycle 12, including operation 13, operation 14, operation 15, operation 16, decision point 17, operation 18, the second cycle 19, including operation 20, operation 21, operation 22, operation 23, decision point 24, and operation 25. In one or more embodiments, the method 10 consists essentially of operation 11, the first cycle 12, including operation 13, operation 14, operation 15, operation 16, decision point 17, operation 18, the second cycle 19, including operation 20, operation 21, operation 22, operation 23, decision point 24, and operation 25. In one or more embodiments, the method 10 consists of operation 11, the first cycle 12, including operation 13, operation 14, operation 15, operation 16, decision point 17, operation 18, the second cycle 19, including operation 20, operation 21, operation 22, operation 23, decision point 24, and operation 25.

Without intending to be bound by theory, it is thought that the second nitrogen-containing plasma mixture comprising nitrogen (N₂) and one or more of argon (Ar) and helium (He) densifies the second silicon nitride (SiₓN_{y}) layer 56 by cross-linking the bonding between the silicon atoms from the second silicon-containing precursor and reactive nitrogen species from the second nitrogen-containing plasma mixture comprising nitrogen (N₂) and one or more of argon (Ar) and helium (He), e.g. nitrogen radicals and nitrogen ions.

Each of the plasmas used in method 10, e.g., the first plasma comprising one or more of ammonia (NH₃) or hydrogen (H₂) (operation 15 in the first cycle 12), the second plasma comprising nitrogen (N₂) used to treat the first silicon nitride (SiₓN_{y}) layer 54 to form the treated silicon nitride (SiₓN_{y}) layer 54′ (operation 18), and/or the at least one nitrogen-containing plasma mixture used in operation 22 of the second cycle 19 may be independently generated by any suitable plasma source. In one or more embodiments, a remote plasma source, an inductively coupled plasma (ICP) source, a capacitively coupled plasma (CCP) source, or a microwave plasma source may be used to generate any of the disclosed plasmas.

The skilled artisan will appreciate that any remote plasma source, inductively coupled plasma (ICP) source, capacitively coupled plasma source (CCP) source, or microwave plasma source that is suitable for generating any of the disclosed plasmas and may be implemented for the disclosed methods.

One or more embodiments of the present disclosure include modular microwave plasma processing tools. Modular microwave plasma sources have a high plasma density and very low plasma potential (e.g., less than or equal to 10 eV).

It has been advantageously found that where the plasma source used to generate the third plasma is turned on after the plasma source used to generate the second plasma is turned off with a time delay of greater than or equal to 0.2 seconds, such as in a range of from 0.2 seconds to 0.5 seconds, the thickness non-uniformity of the silicon nitride (SiₓN_{y}) film is less than or equal to 3%, less than or equal to 2%, less than or equal to 1.5%, or less than or equal to 1%.

The method 10 may be performed at any suitable processing conditions, and the processing conditions may vary depending upon the application for which the silicon nitride (SiₓN_{y}) film is formed.

FIG. 2A-2C illustrate cross-sectional schematic views of the substrate 50. The substrate 50 can be any suitable substrate material. In one or more embodiments, the substrate 50 comprises a semiconductor material, e.g., any metal material, one or more of silicon (Si), germanium (Ge), silicon germanium (SiGe), tungsten (W), nickel (Ni), cobalt (Co), or titanium (Ti).

In FIG. 2A, the first silicon nitride (SiₓN_{y}) layer 54 is formed on a top surface 52 of the substrate 50. In accordance with the method 10, at decision point 17, the substrate 50 is evaluated to determine whether or not the first silicon nitride (SiₓN_{y}) layer 54 has reached a predetermined thickness or a predetermined number of cycles have been performed. In one or more embodiments, the first silicon nitride (SiₓN_{y}) layer 54 has a thickness in a range of from 0 Å to 15 Å.

FIG. 2B illustrates the treatment process of operation 18, denoted by the arrows pointed towards a top surface of the first silicon nitride (SiₓN_{y}) layer 54 to form the treated first silicon nitride (SiₓN_{y}) layer 54′.

FIG. 2C illustrates deposition of the second silicon nitride (SiₓN_{y}) layer 56 directly on a top surface 55 of the treated first silicon nitride (SiₓN_{y}) layer 54′ by the plasma-enhanced atomic layer deposition (PEALD) process of the second cycle 19. In accordance with the method 10, at decision point 24, the substrate 50 is evaluated to determine whether or not the second silicon nitride (SiₓN_{y}) layer 56 has reached a predetermined thickness or a predetermined number of cycles have been performed. The second silicon nitride (SiₓN_{y}) layer 56 can have any suitable thickness.

Further aspects of the disclosure pertain to a method that is part of a gap fill process. The disclosed methods may be utilized with any device nodes, but may be particularly advantageous in device nodes of about 25 nm or less, for example about 5 nm to about 25 nm. In some embodiments, the first silicon nitride (SiₓN_{y}) layer 54 is deposited in at least one feature comprising a trench (e.g., a gap) having a top, two sidewalls comprising, for example, a dielectric material, and a bottom extending into the substrate, the bottom comprising, for example, a metallic material. In some embodiments, the first silicon nitride (SiₓN_{y}) layer 54 is deposited on the two opposed sidewalls, the first silicon nitride (SiₓN_{y}) layer 54 is treated to form the treated first silicon nitride (SiₓN_{y}) layer 54′, and the second silicon nitride (SiₓN_{y}) layer 56 is deposited directly on the top surface 55 of the treated first silicon nitride (SiₓN_{y}) layer 54′ in the gap.

It will be appreciated by the skilled artisan that the method that is part of a gap fill process can include one or more subsequent operations after depositing the first silicon nitride (SiₓN_{y}) layer 54, treating the first silicon nitride (SiₓN_{y}) layer 54 to form the treated first silicon nitride (SiₓN_{y}) layer 54′, and depositing the second silicon nitride (SiₓN_{y}) layer 56 directly on the top surface 55 of the treated first silicon nitride (SiₓN_{y}) layer 54′ in the gap, such as, for example, filling the gap with a conductive material, to form an interconnect, and that the one or more subsequent operations can be performed without undue experimentation.

The methods described herein may be performed in any suitable processing chamber known to the skilled artisan. The methods described herein may be performed in, for example, a PEALD processing chamber.

Embodiments of the disclosure are directed to processing tools. In some embodiments, the processing tool comprises: a central transfer station comprising a robot configured to move a semiconductor, a plurality of process stations, and a controller connected to the central transfer station and the plurality of process stations. In some embodiments, each process station is connected to the central transfer station and provides a processing region separated from processing regions of adjacent process stations. In some embodiments, the plurality of process stations comprises a plasma-enhanced atomic layer deposition (PEALD) chamber. In some embodiments, the controller is configured to activate the robot to move the wafer between process stations, and to control a processing method, such as method 10, to deposit silicon nitride (SiₓN_{y}).

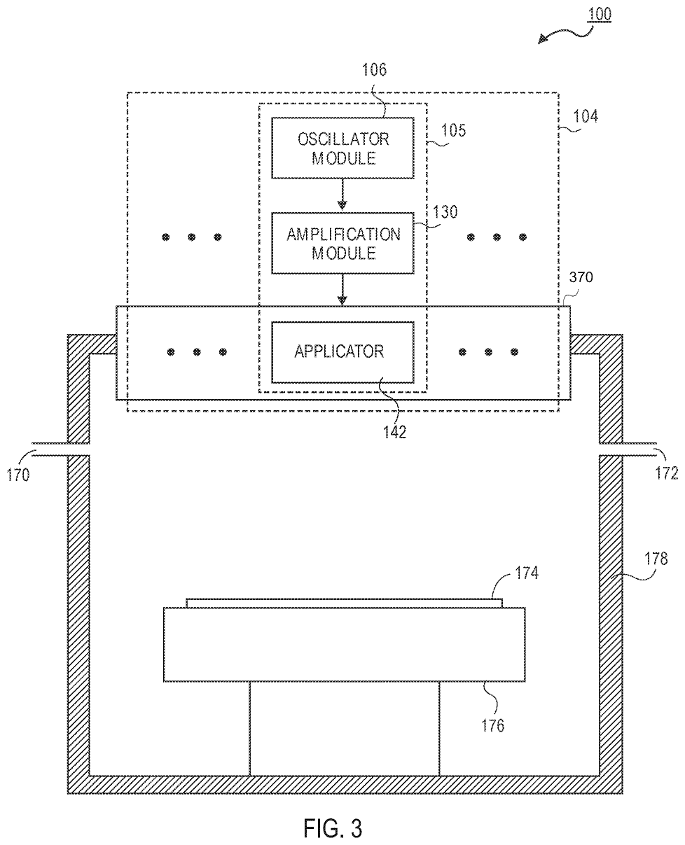

In accordance with one or more embodiments, FIG. 3 illustrates a schematic representation of a processing tool 100. In some embodiments, the processing tool 100 may be a processing tool suitable for any type of processing operation that utilizes a plasma. For example, the processing tool 100 may be a processing tool used for plasma enhanced chemical vapor deposition (PECVD), plasma-enhanced atomic layer deposition (PEALD), etch and selective removal processes, and plasma cleaning. In one or more embodiments, the processing tool 100 is used for plasma-enhanced atomic layer deposition (PEALD) of silicon nitride (SiₓN_{y}) according to the methods described herein, e.g., method 10.

The processing tool 100 includes a semiconductor processing chamber 178. In one or more embodiments, the semiconductor processing chamber 178 is a vacuum chamber. In one or more unillustrated embodiments, the vacuum chamber may include a pump for removing gases from the chamber to provide the desired vacuum. Additional embodiments may include a semiconductor processing chamber 178 that includes one or more gas lines 170 for providing processing gasses into the semiconductor processing chamber 178 and exhaust lines 172 for removing byproducts from the semiconductor processing chamber 178. While not shown, it is to be appreciated that gas may also be injected into the semiconductor processing chamber 178 through a plasma showerhead assembly, e.g., assembly 370 for evenly distributing the processing gases over a substrate 174.

In one or more embodiments, the substrate 174 is supported on a chuck 176. For example, the chuck 176 may be any suitable chuck, such as an electrostatic chuck. The chuck 176 may also include cooling lines and/or a heater to provide temperature control to the substrate 174 during processing. Due to the modular configuration of the high-frequency emission modules described herein, embodiments allow for the processing tool 100 to accommodate any sized substrate 174. For example, the substrate 174 may be a semiconductor wafer (e.g., 200 mm, 300 mm, 450 mm, or larger). Alternative embodiments also include substrates 174 other than semiconductor wafers. For example, embodiments may include a processing tool 100 configured for processing glass substrates, (e.g., for display technologies).

In one or more embodiments, the processing tool 100 includes a modular high-frequency emission source 104. The modular high-frequency emission source 104 includes an array of high-frequency emission modules 105. In one or more embodiments, each high-frequency emission module 105 independently includes an oscillator module 106, an amplification module 130, and an applicator 142. The oscillator module 106 may include a plurality of oscillator modules 106. The applicators 142 are schematically shown as being integrated into the dielectric faceplate 350. The skilled artisan will appreciate that the disclosure is not limited to the applicators 142 being integrated into the assembly 370.

In one or more embodiments, the oscillator module 106 and the amplification module 130 may comprise electrical components that are solid state electrical components. In one or more embodiments, each of the plurality of oscillator modules 106 are independently communicatively coupled to different amplification modules 130. In some embodiments there may be a 1:1 ratio between oscillator modules 106 and amplification modules 130. For example, each oscillator module 106 may be electrically coupled to a single amplification module 130.

In one or more embodiments, each oscillator module 106 independently generates high-frequency electromagnetic radiation that is transmitted to the amplification module 130. After processing by the amplification module 130, the electromagnetic radiation is transmitted to the applicator 142. In one or more embodiments, the applicators 142 each emit electromagnetic radiation into the semiconductor processing chamber 178.

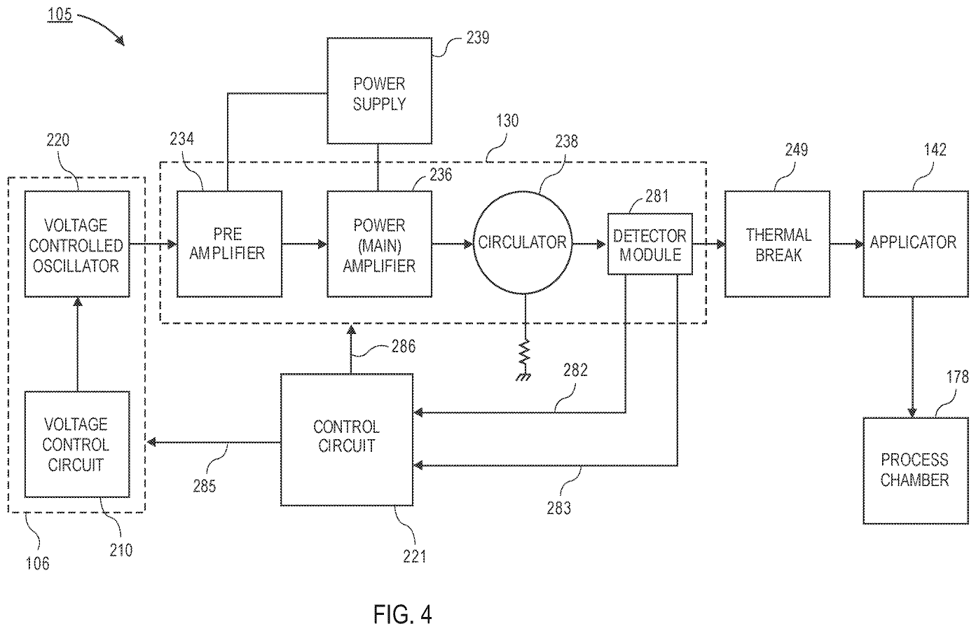

FIG. 4 illustrates a block diagram of a high-frequency emission module 105. In one or more embodiments, the high-frequency emission module 105 comprises the plurality of oscillator modules 106. Each oscillator module 106 may independently include a voltage control circuit 210 for providing an input voltage to a voltage controlled oscillator 220 in order to produce high-frequency electromagnetic radiation at a desired frequency. One or more embodiments include an input voltage in a range of from 1 V to 10V of DC. In one or more embodiments, the voltage controlled oscillator 220 is an electronic oscillator whose oscillation frequency is controlled by the input voltage. According to one or more embodiments, the input voltage from the voltage control circuit 210 results in the voltage controlled oscillator 220 oscillating at a desired frequency. In some embodiments, the high-frequency electromagnetic radiation has a frequency in a range of from about 0.1 MHz to about 30 MHz. In some embodiments, the high-frequency electromagnetic radiation has a frequency in a range of from about 30 MHz to about 300 MHz. In some embodiments, the high-frequency electro-magnetic radiation has a frequency in a range of from about 300 MHz to about 1 GHz. In some embodiments, the high-frequency electromagnetic radiation has a frequency in a range of from about 1 GHz to about 300 GHz.

According to one or more embodiments, the electromagnetic radiation is transmitted from the voltage controlled oscillator 220 to the amplification module 130. The amplification module 130 may include a driver/pre-amplifier 234 and a main power amplifier 236, and each of the driver/pre-amplifier 234 and the main power amplifier 236 are independently coupled to a power supply 239. According to one or more embodiments, the amplification module 130 may operate in a pulse mode. For example, the amplification module 130 may have a duty cycle in a range of from 1% to 99%. In specific embodiments, the amplification module 130 may have a duty cycle in a range of from 15% to 50%.

In some embodiments, the electromagnetic radiation may be transmitted to the thermal break 249 and the applicator 142 after being processed by the amplification module 130. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. The skilled artisan will appreciate that the detector module 281 may be located at one or more different locations in the system (e.g., between the circulator 238 and the thermal break 249). In some embodiments, the control circuit module 221 interprets the forward power 283 and the reflected power 282, and determines the level for the control signal 285 that is communicatively coupled to the oscillator module 106 and the level for the control signal 286 that is communicatively coupled to the amplification module 130. In some embodiments, control signal 285 adjusts the oscillator module 106 to optimize the high-frequency radiation coupled to the amplification module 130. In some embodiments, control signal 286 adjusts the amplification module 130 to optimize the output power coupled to the applicator 142 through the thermal break 249.

Accordingly, one or more embodiments allow for an increased percentage of the forward power to be coupled into the semiconductor processing chamber 178, and increases the available power. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage controlled oscillator 220.

In some embodiments, a total delivered power from the microwave source is equal to level of forward power 283 minus the level of reflected power 282. In some embodiments, the total delivered power from microwave source is in a range of about 2300 Watts (W) to about 3800 Watts (W), such as, for example, 3325 Watts (W).

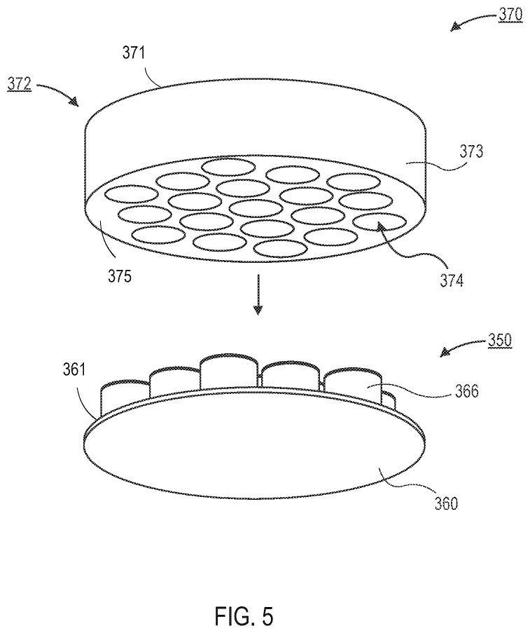

Referring now to FIG. 5, a schematic exploded perspective view of a plasma showerhead assembly, e.g., the assembly 370 is shown.

The assembly 370 comprises a conductive plate 372 and a dielectric faceplate 350. As indicated by the arrow, the conductive plate 372 fits over and around the dielectric faceplate 350. In the illustrated embodiment, the assembly 370 is shown as having a substantially circular shape. However, the skilled artisan will appreciate that the assembly 370 may have any suitable shape such as polygonal, elliptical, wedge shaped, or the like.

The conductive plate 372 comprises a conductive body 373 including a first surface 371 and a second surface 375 opposite to the first surface defining a conductive plate thickness, a plurality of resonator openings 374 extending from the first surface 371 through the conductive plate 372 to the second surface 375 of the conductive plate 372, gas channels within the conductive plate thickness, a plurality of conductive plate gas openings on the second surface 375 of the conductive plate 372 in fluid communication with the gas channels within the conductive plate thickness.

In some embodiments, the dielectric faceplate 350 comprises a first surface 361 and a second surface 360 opposite to the first surface 361 defining a dielectric faceplate thickness, a plurality of dielectric resonators 366 protruding from the first surface 361 and configured so that the resonators 366 fit into the plurality of the resonator openings 374 of the conductive plate 372 when assembled, each resonator 366 having a geometric center; and a plurality of dielectric faceplate gas openings extending through the dielectric faceplate thickness.

The conductive body 373 may include any suitable conductive material. For example, the conductive body 373 may be aluminum or the like. The plurality of resonator openings 374 may pass entirely through a thickness of the conductive body 373. The resonator openings 374 may be sized to receive the dielectric resonators 366. For example, as the conductive plate 372 is displaced towards the dielectric faceplate 350 (as indicated by the arrow in FIG. 5) the dielectric resonators 366 will be inserted into the plurality of resonator openings 374.

In the illustrated embodiment of FIG. 5, the conductive plate 372 is shown as a single conductive body 373. However, the skilled artisan will appreciate that the conductive plate 372 may comprise one or more discrete conductive components. The discrete components may be individually grounded, or the discrete components may be joined mechanically or by any form of metallic bonding, to form a single electrically conductive body 373.

In some embodiments, the dielectric faceplate 350 and the plurality of dielectric resonators 366 are a monolithic structure. That is, in embodiments where the dielectric faceplate 350 and the plurality of dielectric resonators 366 are a monolithic structure, there is no physical interface between a bottom of the dielectric resonators 366 and the dielectric faceplate 350. As used herein, a “physical interface” refers to a first surface of a first discrete body contacting a second surface of a second discrete body.

In other embodiments, the dielectric faceplate 350 and the dielectric resonators 366 are discrete components. Each of the dielectric resonators 366 are a portion of the applicator 142 used to inject high-frequency electromagnetic radiation into a processing chamber, such as the semiconductor processing chamber 178.

In some embodiments, the dielectric faceplate 350 comprises a dielectric material. For example, the dielectric faceplate 350 may be a ceramic material. In some embodiments, one suitable ceramic material that may be used for the dielectric faceplate 350, as an example, is aluminum oxide (Al₂O₃). In specific embodiments where the dielectric faceplate 350 and the plurality of dielectric resonators 366 are a monolithic structure, the monolithic structure may be fabricated from a single block of material. In other embodiments, a rough shape of the dielectric faceplate 350 may be formed with a molding process, and subsequently machined to provide the final structure with the desired dimensions. For example, green state machining and firing may be used to provide the desired shape of the dielectric faceplate 350. In the illustrated embodiment, the dielectric resonators 366 are shown as having a circular cross-section (when viewed along a plane parallel to the dielectric faceplate 350). However, the skilled artisan will appreciate that the dielectric resonators 366 may comprise many different cross-sections. For example, the cross-section of the dielectric resonators 366 may have any shape that is centrally symmetric.

In one or more unillustrated embodiments, the dielectric faceplate 350 includes one or more rings configured to separate the sidewall of the plurality of resonator openings 374 in the conductive plate 372 from the sidewall of the dielectric resonator 366. The rings may be electrically coupled to the conductive body 373 and are grounded during operation of the processing tool. Accordingly, the entire length of the sidewall is covered by a grounded surface. It has been advantageously found that covering the entire length of the sidewall with a grounded surface improves the resonance characteristics of the dielectric faceplate 350, and provides improved coupling of the high-frequency electromagnetic radiation into the processing chamber, such as semiconductor processing chamber 178.

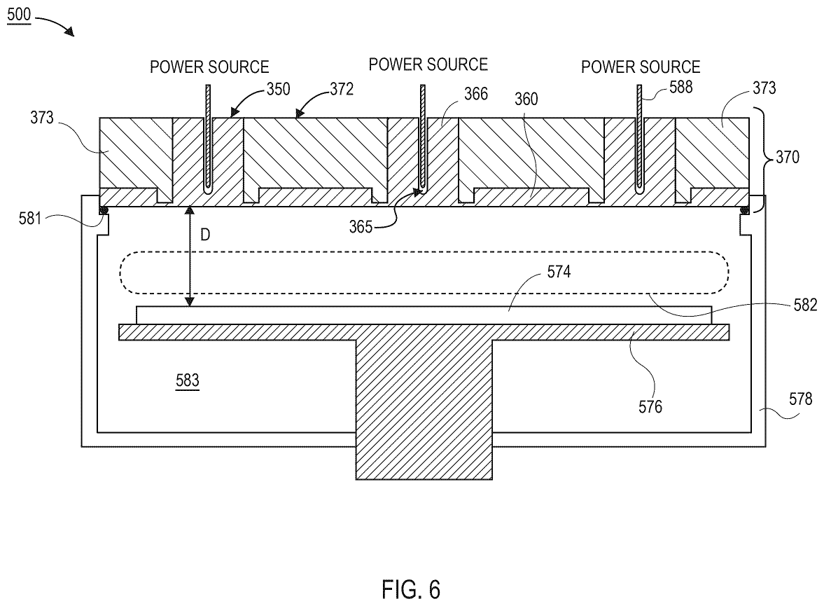

FIG. 6 illustrates a cross-sectional view of a processing tool 500 according to one or more embodiments. In one or more embodiments, the processing tool 500 comprises a semiconductor processing chamber 578 that is sealed by an assembly 370. For example, the assembly 370 may rest against one or more o-rings 581 to provide a vacuum seal to an interior volume 583 of the semiconductor processing chamber 578. In other embodiments, the assembly 370 may interface with the semiconductor processing chamber 578. That is, the assembly 370 may be part of a lid that seals the semiconductor processing chamber 578. In some embodiments, the processing tool 500 may comprise a plurality of processing volumes (which may be fluidically coupled together), with each processing volume independently having a plasma showerhead assembly, such as, for example the assembly 370.

In some embodiments, a chuck 576 or the like may support a workpiece 574 (e.g., wafer, substrate, etc.). In one or more embodiments, the assembly 370 is spaced a distance D from the workpiece 574. The distance D may be any suitable distance. In some embodiments, the chamber interior volume 583 may be suitable for striking a plasma 582. That is, the semiconductor processing chamber 578 may be a vacuum chamber.

In some embodiments, monopole antennas 588 may extend into holes 365 in the dielectric resonators 366. The monopole antennas 588 are each electrically coupled to power sources (e.g., high-frequency emission modules 105).

In one or more embodiments, the substrate 50 is the substrate 174 in the processing tool 100. In one or more embodiments, the substrate 50 is the workpiece 574 in the processing tool 500. The methods of depositing SiₓN_{y} described herein, e.g., the method 10 may be implemented in any of the processing tools described herein.

One or more embodiments of the disclosure are directed to a non-transitory computer readable medium including instructions, that, when executed by a controller of a processing chamber, cause the processing chamber to perform one or more of the operations of method 10.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of depositing silicon nitride (SiₓN_{y}), the method comprising:
exposing a substrate in a semiconductor processing chamber to a first silicon-containing precursor;
exposing the substrate to a first plasma comprising one or more of ammonia (NH₃) or hydrogen (H₂) to form a first silicon nitride (SiₓN_{y}) layer directly on the substrate;
treating the first silicon nitride (SiₓN_{y}) layer with a second plasma comprising nitrogen (N₂) to form a treated first silicon nitride (SiₓN_{y}) layer; and
depositing a second silicon nitride (SiₓN_{y}) layer directly on the treated first silicon nitride (SiₓN_{y}) layer by a plasma-enhanced atomic layer deposition (PEALD) process.

2. The method of claim 1, wherein the substrate comprises one or more of silicon (Si), germanium (Ge), silicon germanium (SiGe), tungsten (W), nickel (Ni), cobalt (Co), or titanium (Ti).

3. The method of claim 1, wherein each of the first plasma, the second plasma, and the plasma used in the PEALD process is independently generated by a plasma source comprising one or more of a remote plasma source, an inductively coupled plasma (ICP) source, a capacitively coupled plasma (CCP) source, or a microwave plasma source.

4. The method of claim 3, wherein each of the first plasma, the second plasma, and the plasma used in the PEALD process independently comprises a microwave plasma.

5. The method of claim 1, wherein the first silicon nitride (SiₓN_{y}) layer is formed at a pressure in a range of from 0.1 Torr to 20 Torr.

6. The method of claim 1, wherein the first silicon nitride (SiₓN_{y}) layer is formed at a temperature in a range of from 100° C. to 600° C.

7. The method of claim 1, wherein the first silicon nitride (SiₓN_{y}) layer has a thickness in a range of from 0 Å to 15 Å.

8. The method of claim 2, wherein the first silicon nitride (SiₓN_{y}) layer prevents formation of one or more of silicon nitride (SiₓN_{y}), germanium nitride (GeNₓ), silicon germanium nitride (SiGeNₓ), tungsten nitride (WNₓ), nickel nitride (NiNₓ), cobalt nitride (CoNₓ), or titanium nitride (TiNₓ) from the substrate.

9. The method of claim 1, wherein the first plasma further comprises argon (Ar).

10. The method of claim 1, wherein the first plasma further comprises nitrogen (N₂) and argon (Ar).

11. The method of claim 1, wherein the first plasma further comprises helium (He).

12. The method of claim 1, wherein the first plasma further comprises nitrogen (N₂) and helium (He).

13. The method of claim 1, wherein the second plasma comprises nitrogen (N₂) and argon (Ar).

14. The method of claim 1, wherein the second plasma comprises nitrogen (N₂) and helium (He).

15. The method of claim 1, wherein the PEALD process comprises:
exposing the substrate to a second silicon-containing precursor;
exposing the substrate to a first nitrogen-containing plasma mixture comprising ammonia (NH₃), nitrogen (N₂), and one or more of argon (Ar) or helium (He); and
exposing the substrate to a second nitrogen-containing plasma mixture comprising nitrogen (N₂) and one or more of argon (Ar) or helium (He).

16. The method of claim 15, wherein the first nitrogen-containing plasma mixture comprises ammonia (NH₃), nitrogen (N₂), and argon (Ar).

17. The method of claim 15, wherein the first nitrogen-containing plasma mixture comprises ammonia (NH₃), nitrogen (N₂), and helium (He).

18. The method of claim 15, wherein the second nitrogen-containing plasma mixture comprises nitrogen (N₂) and argon (Ar).

19. The method of claim 15, wherein the second nitrogen-containing plasma mixture comprises nitrogen (N₂) and helium (He).

20. The method of claim 15, wherein the PEALD process comprises:
exposing the substrate to the second silicon-containing precursor;
exposing the substrate to the second nitrogen-containing plasma mixture comprising nitrogen (N₂) and one or more of argon (Ar) or helium (He); and
exposing the substrate to the first nitrogen-containing plasma mixture comprising ammonia (NH₃), nitrogen (N₂), and one or more of argon (Ar) or helium (He).
